(19) United States
(12) Patent Application Publication
(10) Pub. No.: US 2007/0249167 A1
(43) Pub. Date: Oct. 25, 2007

(54) CMP method for copper-containing substrates

(75) Inventors: Jian Zhang, Aurora, IL (US); Phillip W. Carter, Naperville, IL (US); Shoutian Li, Naperville, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(73) Assignee: Cabot Microelectronics Corporation, Aurora, IL (US)

(21) Appl. No.: 11/408,334

(22) Filed: Apr. 21, 2006

(51) Int. Cl. B24D 3/02; H01L 21/461; H01L 21/302

(52) U.S. Cl. 438/692; 51/307; 51/308; 51/309; 438/693

(57) ABSTRACT

The invention provides a chemical-mechanical polishing composition comprising an abrasive, a benzotriazole derivative, an oxidizing agent selected from the group consisting of iodate compounds, organic oxidizing agents, and mixtures thereof, and water, wherein the polishing composition comprises substantially no organic carboxylic acid having a molecular weight of less than about 500 Daltons, and wherein the polishing composition comprises no alkyl sulfate having a molecular weight of less than about 500 Daltons. The invention further provides a method of chemically-mechanically polishing a substrate with the aforementioned polishing composition.

### FIELD OF THE INVENTION

The invention pertains to chemical-mechanical polishing compositions and methods.

### BACKGROUND OF THE INVENTION

Development of the next generation of semiconductor devices has emphasized the use of metals with lower resistivity values, such as copper, than previous generation metals such as aluminum in order to reduce capacitance between conductive layers on the devices and to increase the frequency at which a circuit can operate. The use of copper in semiconductor device manufacturing presents special challenges in that prior art processes such as deposition and etch processes have proven unsatisfactory due to difficulties in etching copper. Thus, new methods for manufacturing interconnects using copper have been developed.

One such method is referred to as the damascene process. In accordance with this process, the surface of the dielectric material, which typically comprises doped silicon dioxide, undoped silicon dioxide, or a low-K dielectric, is patterned by a conventional dry etch process to form holes and trenches for vertical and horizontal interconnects. The patterned surface is coated with a diffusion barrier layer such as tantalum, tantalum nitride, titanium, or titanium nitride. The diffusion barrier layer is then over-coated with a copper layer. Chemical-mechanical polishing is employed to reduce the thickness of the copper over-layer, as well as the thickness of any adhesion-promoting layer and/or diffusion barrier layer, until a planar surface that exposes elevated portions of the silicon dioxide surface is obtained. The vias and trenches remain filled with electrically conductive copper forming the circuit interconnects.

The necessity of providing a diffusion barrier layer between the copper and dielectric materials is due to the tendency of copper to diffuse into the surrounding dielectric material. Tantalum and tantalum nitride have found wide acceptance in the industry as barrier layer materials and are typically applied to a substrate by physical vapor deposition (PVD) prior to deposition of copper. Planarization of the substrate thus requires removal of copper and then the diffusion barrier to expose the underlying dielectric and complete production of the circuit.

The properties of tantalum and tantalum nitride differ from those of copper, being considerably more chemically inert, such that polishing compositions suitable for the polishing of copper are often unsuitable for the removal of underlying tantalum and tantalum nitride. Thus, a two-step approach is generally used for the polishing of copper-tantalum substrates, with the first step employing a first polishing composition to remove most of the copper, and the second step employing a second polishing composition to remove the remaining copper and the barrier film (e.g., tantalum).

Typically, tantalum polishing compositions have been formulated with a highly basic pH of 9 or more. The basic polishing compositions tend to also exhibit high removal rates for underlying dielectric layers, which can lead to erosion of the substrate and result in nonplanarity of the substrate. Recently, acidic tantalum polishing compositions have been developed having pH values of less than 4. Although such acidic polishing compositions are selective for tantalum over dielectric layers, the copper features tend to suffer from pitting defects at such low pH values.

In addition, tantalum polishing compositions typically contain an oxidizing agent in order to remove residual copper remaining from the copper removal step. The oxidizing agent, however, increases the copper removal rate exhibited by the tantalum polishing compositions so that during the tantalum removal process, copper remaining within the trenches is simultaneously removed. This within-trench copper removal is particularly problematic in wider lines and is referred to as “dishing.” Dishing leads to nonplanarity of the polishing surface, as well as to potential damage to the copper lines.

To this end, polishing compositions intended for use with copper-containing substrates have been devised which include inhibitors of copper overpolishing that act by reducing etching of copper within trenches by the oxidizing agent and other components of polishing compositions. Typically, such inhibitors comprise nitrogen-containing compounds, for example, amines and small molecular weight nitrogen-containing heterocyclic compounds such as benzotriazole, 1,2,3-triazole, and 1,2,4-triazole. For example, U.S. Pat. No. 6,585,568 describes a CMP polishing slurry for polishing a copper-based metal film formed on an insulating film, comprising a polishing material, an oxidizing agent, and water, as well as a benzotriazole compound and a triazole compound, wherein the ratio of the triazole compound to the benzotriazole compound is 5 to 70. U.S. Pat. No. 6,375,693 discloses a slurry for polishing a tantalum-based barrier layer for copper-based metallurgy, consisting of hydrogen peroxide for oxidizing copper, a copper oxidation inhibitor, a sulfated fatty acid surfactant that regulates complexing between copper and the oxidation inhibitor, and colloidal silica, wherein the oxidation inhibitor is selected from the group consisting of 1-H benzotriazole, 1-hydroxybenzotriazole, 1-methylbenzotriazole, 5-methylbenzotriazole, benzimidazole, 2-methylbenzimidazole, and 5-chlorobenzotriazole.

However, despite the improvements achieved in the reduction of dishing and erosion in the chemical-mechanical polishing of copper/tantalum substrates with the use of heterocyclic copper inhibitors, problems with pitting and dishing remain, particularly at low pH values. Further, polishing compositions suitable for copper remain substantially different from polishing compositions suitable for tantalum, thereby requiring a two-step process for the planarization of such substrates. Thus, there remains a need in the art for improved polishing systems and methods for the chemical-mechanical planarization of substrates comprising copper and tantalum layers.

### BRIEF SUMMARY OF THE INVENTION

The invention provides a chemical-mechanical polishing composition comprising, consisting essentially of, or consisting of (a) an abrasive, (b) about 0.5 mM to about 100 mM of a benzotriazole compound having the general structure 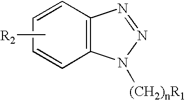
wherein R₁ is selected from the group consisting of H, —OH, —CHO, —CN, and —NC, n is an integer of 0 to about 6, and R₂ is selected from the group consisting of H, C₁-C₆ alkyl, F, Cl, and Br, with the proviso that when R₁ is H and n=0, then R₂ cannot be H, (c) an oxidizing agent selected from the group consisting of iodate compounds, organic oxidizing agents, and mixtures thereof, and (d) water, wherein the polishing composition comprises substantially no organic carboxylic acid having a molecular weight of less than about 500 Daltons, and wherein the polishing composition comprises no alkyl sulfate having a molecular weight of less than about 500 Daltons.

The invention also provides a method of chemically-mechanically polishing a substrate, which method comprises (i) providing a substrate, (ii) contacting the substrate with a polishing pad and a chemical-mechanical polishing composition comprising, consisting essentially of, or consisting of (a) an abrasive, (b) about 0.5 mM to about 100 mM of a benzotriazole compound having the general structure 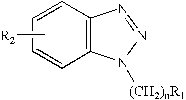
wherein R₁ is selected from the group consisting of H, —OH, —CHO, —CN, and —NC, n is an integer of 0 to about 6, and R₂ is selected from the group consisting of H, C₁-C₆ alkyl, F, Cl, and Br, with the proviso that when R₁ is H and n=0, then R₂ cannot be H, (c) an oxidizing agent selected from the group consisting of iodate compounds, organic oxidizing agents, and mixtures thereof, and (d) water, wherein the polishing composition comprises substantially no organic carboxylic acid having a molecular weight of less than about 500 Daltons, and wherein the polishing composition comprises no alkyl sulfate having a molecular weight of less than about 500 Daltons, (ii) moving the polishing pad relative to the substrate with the chemical-mechanical polishing composition therebetween, and (iii) abrading at least a portion of the substrate to polish the substrate.

### BRIEF DESCRIPTION OF THE SEVERAL VIEWS OF THE DRAWINGS

FIG. 1 is a SEM image of a copper blanket wafer surface after polishing with a chemical-mechanical polishing composition comprising benzotriazole.

FIG. 2 is a SEM image of a copper blanket wafer surface after polishing with a chemical-mechanical polishing composition comprising 5-methylbenzotriazole.

FIG. 3 is a SEM image of a copper pattern wafer after polishing with a chemical-mechanical polishing composition comprising benzotriazole.

FIG. 4 is a SEM image of a copper pattern wafer after polishing with a chemical-mechanical polishing composition comprising 5-methylbenzotriazole.

### DETAILED DESCRIPTION OF THE INVENTION

The invention provides a chemical-mechanical polishing composition comprising, consisting essentially of, or consisting of (a) an abrasive, (b) about 0.5 mM to about 100 mM of a benzotriazole compound having the general structure 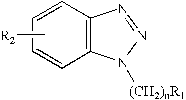
wherein R₁ is selected from the group consisting of H, —OH, —CHO, —CN, and —NC, n is an integer of 0 to about 6, and R₂ is selected from the group consisting of H, C₁-C₆ alkyl, F, Cl, and Br, with the proviso that when R₁ is H and n=0, then R₂ cannot be H, (c) an oxidizing agent selected from the group consisting of iodate compounds, organic oxidizing agents, and mixtures thereof, and (d) water, wherein the polishing composition comprises substantially no organic carboxylic acid having a molecular weight of less than about 500 Daltons, and wherein the polishing composition comprises no alkyl sulfate having a molecular weight of less than about 500 Daltons.

The abrasive can be any suitable abrasive, for example, the abrasive can be natural or synthetic, and can comprise metal oxide, carbide, nitride, carborundum, and the like. The abrasive also can be a polymer particle or a coated particle. The abrasive desirably comprises a metal oxide. Preferably, the metal oxide is selected from the group consisting of alumina, ceria, silica, zirconia, co-formed products thereof, and combinations thereof. More preferably, the metal oxide is silica.

The silica can be any suitable form of silica. Useful forms of silica include but are not limited to fumed silica, precipitated silica, and condensation-polymerized silica. More preferably, the silica is a condensation-polymerized silica. Condensation-polymerized silica particles typically are prepared by condensing Si(OH)₄ to form colloidal particles. The precursor Si(OH)₄ can be obtained, for example, by hydrolysis of high purity alkoxysilanes, or by acidification of aqueous silicate solutions. Such abrasive particles can be prepared in accordance with U.S. Pat. No. 5,230,833 or can be obtained as any of various commercially available products, such as the Fuso PL-1, PL-2, and PL-3 products (Fuso Chemical Company, Ltd., Japan) and the Nalco 1050, 2327, and 2329 products (Nalco Chemical Company, Naperville, Ill.), as well as other similar products available from DuPont, Bayer, Applied Research, Nissan Chemical, and Clariant.

The abrasive also can be an alumina-doped silica. An example of a suitable alumina-doped silica is the Nalco 1034 A product (Nalco Chemical Company).

As is well known in the art, many abrasive particles, such as metal oxide particles, comprise, at the lowest level of structure, primary particles. Primary particles are formed by covalent bonds between atoms comprising the particles and are stable to all but the harshest conditions. At the next level of structure, primary particles are associated into secondary particles, generally referred to as aggregates. Aggregate particles comprise primary particles and are bonded together by covalent bonds and typically are resistant to degradation by, for example, mechanical energy inputs such as high-shear mixing. At the next level of structure, aggregates are more loosely associated into agglomerates. Typically, agglomerates can be disassociated into the constituent aggregates via mechanical energy inputs. Depending on the particular composition and method of preparation, primary particles and secondary particles (e.g., aggregates) can have shapes ranging from spherical to elliptical, and some aggregates can have extended, chain-like structures. For example, pyrogenic, or fumed, silica typically exists in the form of aggregates having a chain-like structure. Precipitated silicas, for example, silicas prepared by neutralization of sodium silicate, have an aggregate structure in which approximately spherical primary particles are associated into aggregates that resemble a “bunch of grapes.” Both primary abrasive particles and aggregated primary particles (e.g., secondary particles) can be characterized as having an average particle size. In this regard, particle size refers to the diameter of the smallest sphere that encloses the particle.

The abrasive typically has an average primary particle size of about 5 nm or more (e.g., about 10 nm or more, or about 15 nm or more, or about 20 nm or more). Preferably, the abrasive has an average primary particle size of about 150 nm or less (e.g., about 100 nm or less, or about 75 nm or less, or about 50 nm or less, or even about 30 nm or less). More preferably, the abrasive has an average primary particle size of about 5 nm to about 50 nm, or about 10 nm to about 40 nm, or about 15 nm to about 35 nm, or about 20 nm to about 30 nm.

When the abrasive comprises aggregates of primary particles, the abrasive typically has an aggregate particle size of about 20 nm or more (e.g., about 30 nm or more, or about 40 nm or more, or about 50 nm or more). Preferably, the abrasive has an aggregate particle size of about 250 nm or less (e.g., about 200 nm or less, or about 150 nm or less, or about 100 nm or less, or even about 75 nm or less). More preferably, the abrasive has an aggregate particle size of about 20 nm to about 125 nm, or about 30 nm to about 100 mm.

The abrasive desirably is suspended in the polishing composition, more specifically in the water of the polishing composition. The polishing composition preferably is colloidally stable. The term colloid refers to the suspension of abrasive particles in the water. Colloidal stability refers to the maintenance of that suspension over time. In the context of this invention, an abrasive composition is considered colloidally stable if, when the abrasive composition is placed into a 100 ml graduated cylinder and allowed to stand unagitated for a time of 2 hours, the difference between the concentration of particles in the bottom 50 ml of the graduated cylinder ([B] in terms of g/ml) and the concentration of particles in the top 50 ml of the graduated cylinder ([T] in terms of g/ml) divided by the initial concentration of particles in the abrasive composition ([α] in terms of g/ml) is less than or equal to 0.5 (i.e., {[B]−[T]}/[α]≦0.5). The value of [B]−[T]/[α] desirably is less than or equal to 0.3, and preferably is less than or equal to 0.1.

Any suitable amount of abrasive can be present in the polishing composition. Typically, about 0.01 wt. % or more abrasive can be present in the polishing composition (e.g., about 0.05 wt. % or more, or about 0.1 wt. % or more). The amount of abrasive in the polishing composition preferably will not exceed about 10 wt. %, and more preferably will not exceed about 5 wt. % (e.g., will not exceed about 2.5 wt. %, or will not exceed about 1 wt. %). Even more preferably the abrasive will comprise about 0.05 wt. % to about 2.5 wt. % (e.g., about 0.1 wt. % to about 1 wt. %) of the polishing composition.

The polishing composition comprises a benzotriazole compound having the general structure 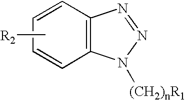
wherein R₁ is selected from the group consisting of H, —OH, —CHO, —CN, and —NC, n is an integer of 0 to about 6 (i.e., 0, 1, 2, 3, 4, 5, or 6), and R₂ is selected from the group consisting of H, C₁-C₆ alkyl, F, Cl, and Br, with the proviso that when R₁ is H and n=0, then R₂ cannot be H. Preferably, n is an integer of 0 to about 3 (i.e., 0, 1, or 2), and R₂ is selected from the group consisting of H, C₁-C₃ alkyl (i.e., —CH₂—, —CH₂CH₂— or —CH₂CH₂CH₂—), F, Cl, and Br, with the proviso that when R₁ is H and n=0, then R₂ cannot be H. More preferably, the benzotriazole is selected from the group consisting of 4-methylbenzotriazole, 5-methylbenzotriazole, 1H-benzotriazole-1-carboxaldehyde, 1-(isocyanomethyl)-1H-benzotriazole, 1H-benzotriazole-1-acetonitrile, 1H-benzotriazole-1-methanol, and combinations thereof.

The polishing composition can comprise any suitable concentration of the benzotriazole compound. Typically, the concentration of the benzotriazole compound in the polishing composition is about 0.5 mM or more (e.g., about 1 mM or more, or about 2 mM or more, or about 5 mM or more). Preferably, the concentration of the benzotriazole compound in the polishing composition is about 100 mM or less (e.g., about 75 mM or less, or about 50 mM or less). More preferably, the concentration of the benzotriazole compound in the polishing composition is about 0.5 mM to about 75 mM (e.g., about 1 mM to about 50 mM, or about 2 mM to about 20 mM, or even about 5 mM to about 20 mM). The desired concentration of the benzotriazole compound can be achieved by any suitable means, such as by using about 0.006 wt. % to about 1.2 wt. % of the benzotriazole compound based on the weight of the water and any components dissolved or suspended therein in the preparation of the polishing composition.

The polishing composition comprises an oxidizing agent selected from the group consisting of iodate compounds, organic oxidizing agents, and mixtures thereof. The iodate compound can be any suitable compound comprising the iodate anion, IO3⁻. Examples of suitable iodate compounds include but are not limited to potassium iodate, ammonium iodate, and tetraalkylammonium iodates.

When the polishing composition comprises an iodate compound, typically the concentration of the iodate compound in the polishing composition is about 0.1 mM or more (e.g., about 0.2 mM or more, or about 0.5 mM or more, or about 1 mM or more). Preferably, the concentration of the iodate compound in the polishing composition is about 1 M or less (e.g., about 0.75 M or less, or about 0.5 M or less, or about 0.25 M or less). More preferably, the concentration of the iodate compound in the polishing composition is about 0.5 mM to about 100 mM (e.g., about 1 mM to about 75 mM, or about 5 mM to about 50 mM).

The organic oxidizing agent can be any suitable organic oxidizing agent wherein the organic oxidizing agent has an oxidized form and a reduced form. The oxidized form of the organic oxidizing agent has a standard reduction potential of greater than about −0.7 volts. The oxidized form of the organic oxidizing agent also comprises at least one aromatic ring in conjugation with at least one additional unsaturated moiety.

The oxidized and reduced form of organic oxidizing agent are related in that the carbon skeletal framework of the organic oxidizing agent, that is, the carbon-carbon bond connectivities that define the structure of the organic oxidizing agent, are the same in both forms. Although the oxidized and the reduced forms of the organic oxidizing agent typically comprise different functional groups that are related in that the functional groups are interconvertible with one another via processes of oxidation and reduction, the overall general structure of the organic oxidizing agent is the same for both forms. Typically, the oxidized form and reduced form of the organic oxidizing agent differ by two electrons, although it is suitable for the oxidized form and reduced form to differ by one (unpaired) electron and thus for one form to exist as a free radical.

Desirably, the organic oxidizing agent will be water-soluble or water-emulsifiable. As utilized herein, the term “water-soluble” refers to an organic oxidizing agent that has a solubility of at least about 0.1 mg/ml (e.g., at least about 1 mg/ml) in water at 25° C. As utilized herein, the term “water-emulsifiable” refers to an organic oxidizing agent that forms a stable, oil-in-water emulsion at 25° C.

The oxidized form of the organic oxidizing agent preferably has a standard reduction potential of greater than about −0.7 volts (e.g., greater than about −0.6 volts, or greater than about −0.5 volts, or even greater than about −0.4 volts), when measured against a standard hydrogen electrode at standard conditions of concentration and temperature. Standard conditions of concentration and temperature are measured at 1 molal concentration for all dissolved materials, 1 atmosphere pressure (101.33 kPa) for all gases, and a system temperature of 25° C.

The organic oxidizing agent can be substituted at any available position with any suitable substituent(s) or combinations of substituents. Preferred substituents include groups that confer solubility or emulsifiability of the organic oxidizing agent in the liquid carrier of the polishing composition. Suitable substituents include, without limitation, hydroxyl, amino, monoalkylamino, dialkylamino, sulfonic acid, phosphonic acid, salts thereof, and combinations thereof. Preferably, the organic oxidizing agent is substituted with one or more sulfonic acid groups (—SO₃H).

It will be appreciated that the acidic substituents are capable of forming salts, and in this regard the organic oxidizing agent having acidic substituents can exist as an acid, salt, or when di- or polysubstituted as a partial salt (e.g., a monosalt of a disulfonic acid). Organic oxidizing agents having acidic substituents can be supplied for use in the inventive polishing composition in either acid form or salt form.

When the organic oxidizing agent comprises an acidic substituent in the form of a salt, the counterion can be any suitable countercation. For example, the countercation can be ammonium, alkylammonium, di-, tri-, and tetra-alkylammonium, cesium, potassium, sodium, and the like. The choice of countercation will depend on the type of substrate being polished and on the solubility or emulsifiability of the particular salt in the liquid carrier.

In a preferred embodiment, the organic oxidizing agent is at least one anthraquinone compound. The anthraquinone compound can be any derivative of the basic structure embodied by the term. Preferred anthraquinone compounds are selected from the group consisting of anthraquinone-2,6-disulfonic acid, anthraquinone-2-sulfonic acid, anthraquinone-1,8-disulfonic acid, anthraquinone-1,5-disulfonic acid, acid blue 45, salts thereof, and combinations thereof.

When the polishing composition comprises an organic oxidizing agent, typically the concentration of the organic oxidizing agent in the polishing composition is about 0.1 mM or more (e.g., about 0.2 mM or more, or about 0.5 mM or more, or about 1 mM or more). Preferably, the concentration of the organic oxidizing agent in the polishing composition is about 10 mM or less (e.g., about 8 mM or less, or about 6 mM or less). More preferably, the concentration of the organic oxidizing agent in the polishing composition is about 0.2 mM to about 10 mM (e.g., about 0.5 mM to about 8 mM). The desired concentration of organic oxidizing agent can be achieved by any suitable means, such as by using about 0.003 wt. % to about 0.3 wt. % of organic oxidizing agent based on the weight of the water and any components dissolved or suspended therein in the preparation of the polishing composition.

The polishing composition comprises water. Desirably, the water is the liquid carrier for the other components of the polishing composition, i.e., the other components of the polishing composition are dissolved or suspended din the water. The water preferably is deionized water as added to form the polishing composition.

The polishing composition can have any suitable pH. Typically, the polishing composition has a pH of about 1 or more (e.g., about 2 or more). Preferably, the polishing composition has a pH of about 13 or less (e.g., about 12 or less). In one preferred embodiment, the polishing composition has a pH of about 1 to about 7 (e.g., about 2 to about 5, or about 2 to about 4, or even about 2 to about 3).

The pH of the polishing composition can be achieved and/or maintained by any suitable means. More specifically, the polishing composition can further comprise a pH adjustor, a pH buffering agent, or a combination thereof. The pH adjustor can be any suitable pH-adjusting compound. For example, the pH adjustor can be nitric acid, ammonium hydroxide, potassium hydroxide, potassium carbonate, or a combination thereof. The pH buffering agent can be any suitable buffering agent, for example, phosphates, sulfates, borates, ammonium salts, and the like. The polishing composition can comprise any suitable amount of a pH adjustor and/or a pH buffering agent, provided that a suitable amount is used to achieve and/or maintain the pH of the polishing composition within the ranges set forth.

It is well known in the art that when a copper surface is contacted with an oxidizing agent, a layer of copper oxide is formed on the surface of the copper. In order to facilitate the solubilization of the copper oxide to soluble forms of copper (II) ion and thus to enhance the rate at which copper can be removed from a substrate being polished, various additives have been included in chemical-mechanical polishing compositions for use in the polishing of copper. In particular, organic carboxylic acids, dihydroxybenzene compounds, and trihydroxybenzene compounds have been utilized in copper polishing compositions to enhance the polishing rate for copper layers.

In some embodiments, the inventive polishing composition is selective for the polishing of copper versus tantalum. In other embodiments, the inventive polishing composition is selective for the polishing of tantalum versus copper. Advantageously, embodiments of the inventive polishing composition exhibiting selectivity for copper versus tantalum provide for satisfactory copper removal rates without the necessity for incorporation of copper rate enhancing compounds. Moreover, in tantalum-selective embodiments of the inventive polishing composition, copper rate-enhancing compounds disadvantageously reduce the selectivity for tantalum versus copper otherwise exhibited by the inventive polishing compositions. Accordingly, the polishing composition desirably comprises substantially no component that solubilizes, i.e., that acts to solubilize, copper oxide, apart from any inorganic acid and/or buffer used to adjust the pH of the polishing composition. In particular, the polishing composition desirably comprises substantially no organic carboxylic acid having a molecular weight of less than about 500 Daltons, and preferably comprises no organic carboxylic acid, having a molecular weight of less than about 500 Daltons. An organic carboxylic acid is a compound having one or more carboxylic acid functional group(s) represented by —COOH. The polishing composition also desirably comprises no dihydroxybenzene or trihydroxybenzene compound having a molecular weight of less than about 500 Daltons, such as catechol or pyrogallol. Polymeric compounds having molecular weights of about 500 Daltons or more and having multiple carboxylic acid structural groups, such as polyacrylates, vinyl acrylates, and styrene acrylates, are not precluded from being present in the polishing composition. In some embodiments, the polishing composition does not comprise any compound having any number of carboxylic acid functional groups.

The polishing composition optionally further comprises one or more other additives. Such additives include any suitable surfactant and/or rheological control agent, including viscosity enhancing agents and coagulants (e.g., polymeric rheological control agents, such as, for example, urethane polymers), acrylates comprising one or more acrylic subunits (e.g., vinyl acrylates and styrene acrylates), and polymers, copolymers, and oligomers thereof, and salts thereof. Suitable surfactants include, for example, cationic surfactants, nonionic surfactants, amphoteric surfactants, fluorinated surfactants, mixtures thereof, and the like. The polishing composition also optionally comprises a biocide, such as an isothiazolidinone biocide.

The polishing composition desirably comprises no component that competes with the benzotriazole compound for reaction sites on the surface of copper being polished. In particular, the polishing composition desirably comprises no alkyl having a molecular weight of less than about 500 Daltons. Preferably, the polishing composition comprises no alkyl sulfate having a molecular weight of less than about 1000 Daltons (e.g., less than about 10,000 Daltons). Alkyl sulfates are represented by the formula ROSO₃M wherein R represents an alkyl or an alkylaryl, and M is hydrogen, ammonium, tetraalkylammonium, or a metal cation (e.g., sodium).

The polishing composition can be prepared by any suitable technique, many of which are known to those skilled in the art. The polishing composition can be prepared in a batch or continuous process. Generally, the polishing composition can be prepared by combining the components thereof in any order. The term “component” as used herein includes individual ingredients (e.g., abrasive, benzotriazole compound, oxidizing agent, pH adjustor, etc.) as well as any combination of ingredients (e.g., abrasive, benzotriazole compound, oxidizing agent, pH adjustor, etc.).

For example, the abrasive can be dispersed in water. The benzotriazole compound then can be added, and mixed with the abrasive and water by any method that is capable of incorporating the components into the polishing composition. The oxidizing agent can be added at any time during the preparation of the polishing composition. The polishing composition can be prepared prior to use, with one or more components, such as the oxidizing agent, added to the polishing composition just before use (e.g., within about 1 minute before use, or within about 1 hour before use, or within about 7 days before use). The polishing composition also can be prepared by mixing the components at the surface of the substrate during the polishing operation.

The polishing composition can be supplied as a one-package system comprising an abrasive, a benzotriazole compound, an oxidizing agent, and water. Alternatively, the abrasive can be supplied as a dispersion in water in a first container, and the oxidizing agent can be supplied in a second container, either in dry form, or as a solution or dispersion in water, with the benzotriazole compound supplied in the first or second container, or in a third container. Optional components, such as a pH adjustor, can be placed in the first and/or second containers or a third container. Furthermore, the components in the first or second container can be in dry form while the components in the remaining container(s) can be in the form of an aqueous dispersion. Moreover, it is suitable for the components in the first, second, or third containers to have different pH values, or alternatively to have substantially similar, or even equal, pH values. If an optional component such as a pH adjustor or buffer is a solid, it may be supplied either in dry form or as a mixture in water. The oxidizing agent can be supplied separately from the other components of the polishing composition and can be combined, for example, by the end-user, with the other components of the polishing composition shortly before use (e.g., 1 week or less prior to use, 1 day or less prior to use, 1 hour or less prior to use, 10 minutes or less prior to use, or 1 minute or less prior to use). Other two-container, or three or more container, combinations of the components of the polishing composition are within the knowledge of one of ordinary skill in the art.

The polishing composition of the invention also can be provided as a concentrate which is intended to be diluted with an appropriate amount of water prior to use. In such an embodiment, the polishing composition concentrate can comprise the abrasive, benzotriazole compound, oxidizing agent, and water in amounts such that, upon dilution of the concentrate with an appropriate amount of water, each component of the polishing composition will be present in the polishing composition in an amount within the appropriate range recited above for each component. For example, the abrasive, benzotriazole compound, and oxidizing agent can each be present in the concentration in an amount that is about 2 times (e.g., about 3 times, about 4 times, or about 5 times) greater than the concentration recited above for each component so that, when the concentrate is diluted with an equal volume of water (e.g., 2 equal volumes of water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of water present in the final polishing composition in order to ensure that the abrasive, benzotriazole compound, oxidizing agent, and other suitable additives are at least partially or fully dissolved in the concentrate. It is also suitable to provide the polishing composition in the form of two or more concentrates, each concentrate individually containing less than all of the components of the polishing composition, wherein upon combination of the concentrates and dilution of the combination with an appropriate amount of water, each component of the polishing composition will be present in the polishing composition in an amount within the appropriate range recited above for each component.

The invention also provides a method of polishing a substrate with the polishing composition described herein. The method of polishing a substrate comprises (i) contacting a substrate with the aforementioned polishing composition, and (ii) abrading or removing at least a portion of the substrate to polish the substrate.

In particular, the invention provides a method of chemically-mechanically polishing a substrate comprising (i) providing a substrate, (ii) contacting the substrate with a polishing pad and a chemical-mechanical polishing composition comprising, consisting essentially of, or consisting of (a) an abrasive, (b) about 0.5 mM to about 100 mM of a benzotriazole having the general structure 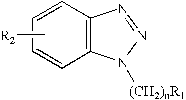
wherein R₁ is selected from the group consisting of H, —OH, —CHO, —CN, and —NC, n is an integer of 0 to about 6, and R₂ is selected from the group consisting of H, C₁-C₆ alkyl, F, Cl, and Br, with the proviso that when R₁ is H and n=0, then R₂ cannot be H, (c) an oxidizing agent selected from the group consisting of iodate compounds, organic oxidizing agents, and mixtures thereof, and (d) water, wherein the polishing composition comprises substantially no organic carboxylic acid having a molecular weight of less than about 500 Daltons, and wherein the polishing composition comprises no alkyl sulfate, (ii) moving the polishing pad relative to the substrate with the chemical-mechanical polishing composition therebetween, and (iii) abrading at least a portion of the substrate to polish the substrate.

Although the polishing composition of the invention is useful for polishing any substrate, the polishing composition is particularly useful in the polishing of a substrate comprising at least one metal layer comprising copper. The substrate can be any suitable substrate (e.g., an integrated circuit, metals, ILD layers, semiconductors, and thin films) and preferably further comprises at least one metal layer comprising tantalum (e.g., a barrier layer). The tantalum can be in the form of tantalum metal, alloys thereof, oxides thereof, nitrides thereof, and combinations thereof. The substrate typically further comprises a suitable insulating layer. The insulating layer can be a metal oxide, porous metal oxide, glass, organic polymer, fluorinated organic polymer, or any other suitable high or low-k insulating layer. The insulating layer preferably is a silicon-based metal oxide, carbon-doped silicon dioxide, or organically modified silicon glass.

The polishing composition of the invention is capable of planarizing or polishing a copper-containing metal layer of a substrate with desirable planarization efficiency, uniformity, removal rate, and low defectivity. The copper removal rate can be controlled by selecting the amount of benzotriazole compound to be incorporated into the polishing composition. With low levels of the benzotriazole compound, the copper removal rate exhibited by the inventive polishing composition can be relatively high, thus allowing use of the polishing composition to polish copper layers rapidly and with minimal pitting of the copper layers. With higher levels of the benzotriazole compound, the copper removal rate exhibited by the inventive polishing composition can be close to zero, thus allowing for the use of the inventive polishing composition in the removal of a barrier layer (e.g., a tantalum layer) on a patterned substrate, with attendant reduction of dishing of copper lines on the substrate.

In some instances, it is desirable to transform the inventive polishing composition from a copper-selective polishing composition to a tantalum-selective polishing composition in situ, e.g., during the polishing process. This can be accomplished by adjusting the concentration of the benzotriazole compound during the polishing process. For example, a substrate comprising a layer of copper over a layer of tantalum can be polished with a polishing composition comprising a concentration of a benzotriazole compound, wherein the polishing composition exhibits a faster removal rate for copper than for tantalum. At a suitable time point during the polishing process, e.g., when substantially or nearly all of the desired copper to be removed has been removed by the polishing composition, the concentration of the benzotriazole compound in the polishing composition can be increased so that the polishing composition exhibits a slower removal rate for copper than for tantalum.

A substrate can be planarized or polished with the polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

Desirably, the CMP apparatus further comprises an in situ polishing endpoint detection system, many of which are known in the art. Techniques for inspecting and monitoring the polishing process by analyzing light or other radiation reflected from a surface of the workpiece are known in the art. Such methods are described, for example, in U.S. Pat. No. 5,196,353, U.S. Pat. No. 5,433,651, U.S. Pat. No. 5,609,511, U.S. Pat. No. 5,643,046, U.S. Pat. No. 5,658,183, U.S. Pat. No. 5,730,642, U.S. Pat. No. 5,838,447, U.S. Pat. No. 5,872,633, U.S. Pat. No. 5,893,796, U.S. Pat. No. 5,949,927, and U.S. Pat. No. 5,964,643. Desirably, the inspection or monitoring of the progress of the polishing process with respect to a workpiece being polished enables the determination of the polishing end-point, i.e., the determination of when to terminate the polishing process with respect to a particular workpiece.

The following examples further illustrate the invention but, of course, should not be construed as in any way limiting its scope.

### EXAMPLE 1

This example demonstrates the effect on copper corrosion of a blanket layer of copper exhibited by the polishing composition of the invention.

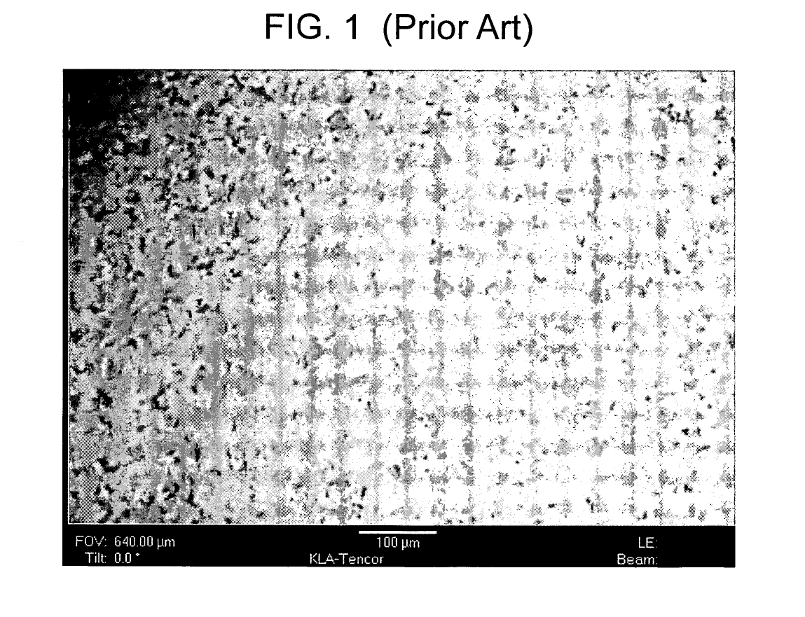

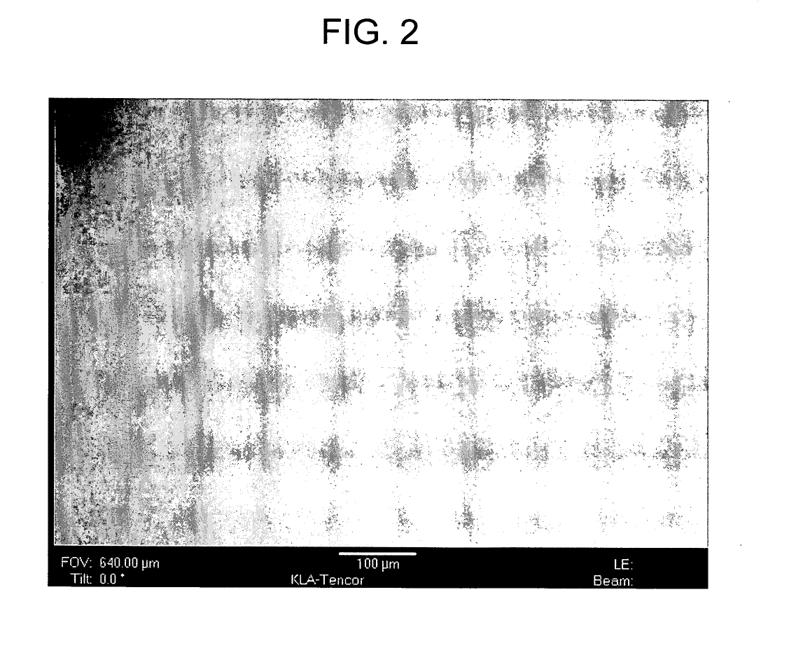

Similar substrates comprising a blanket layer of copper were polished under identical polishing conditions with polishing compositions comprising 1 wt. % of aluminum-doped silica having a 25 nm primary particle size (Nalco 1034 A) and 0.2 wt. % (about 9 mM) potassium iodate in water at a pH of 2.2. Composition 1A (comparative) further comprised 10 mM benzotriazole. Composition 1B (invention) further comprised 10 mM 5-methylbenzotriazole. After polishing, the substrate surfaces were imaged using scanning electron microscopy (SEM). The SEM image of the surface polished with Composition 1A is depicted in FIG. 1, and the SEM image of the surface polished with Composition 1B is depicted in FIG. 2.

As is apparent by visual inspection of the copper surfaces depicted in FIGS. 1 and 2, the inventive polishing composition allows for formation of a copper surface having considerably less pitting than that observed for the control polishing composition.

### EXAMPLE 2

This example demonstrates the effect on copper corrosion of a copper pattern wafer exhibited by the polishing composition of the invention.

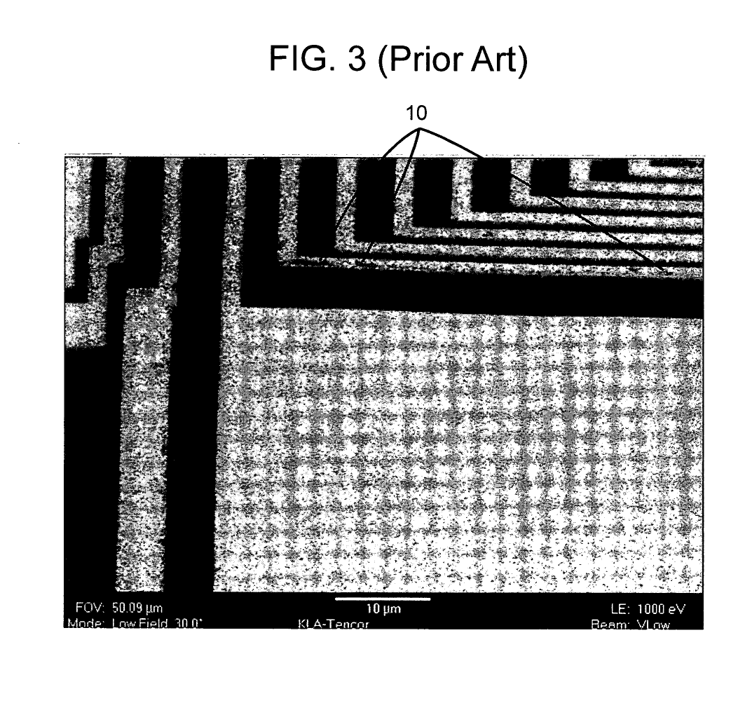

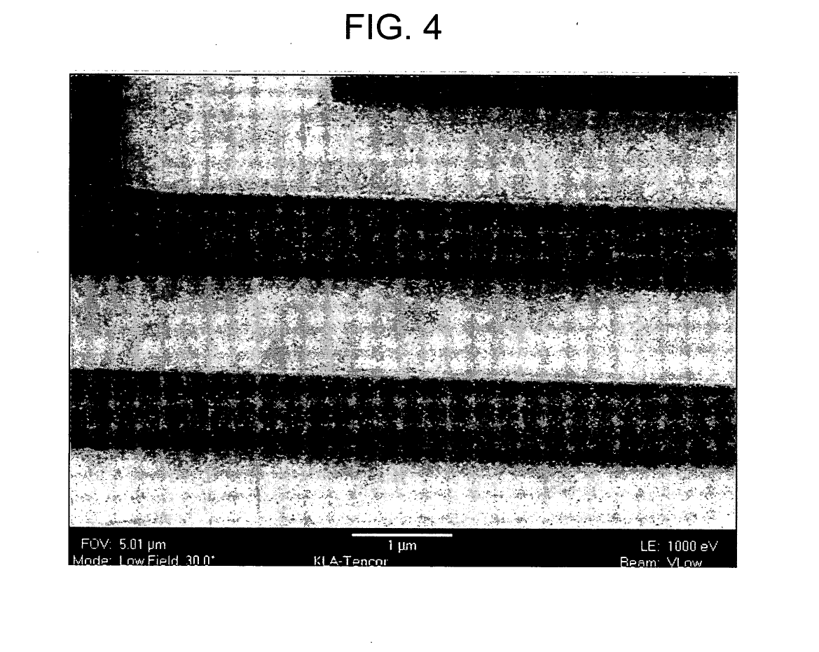

Similar substrates comprising a copper pattern wafer were polished under identical polishing conditions with polishing compositions comprising 1 wt. % of aluminum-doped silica having a 25 nm primary particle size (Nalco 1034 A) and 0.2 wt. % (about 9 mM) potassium iodate in water at a pH of 2.2. Composition 2A (comparative) further comprised 10 mM benzotriazole. Composition 2B (invention) further comprised 10 mM 5-methylbenzotriazole. After polishing, the substrate surfaces were imaged using scanning electron microscopy (SEM). The SEM image of the surface polished with Composition 2A is depicted in FIG. 3, and the SEM image of the surface polished with Composition 2B is depicted in FIG. 4. The magnification of the SEM image depicted in FIG. 4 is about 10× that of FIG. 3.

Regions of corrosion (10) are observed on the copper pattern lines depicted in FIG. 3 after polishing with the comparative polishing composition. By way of contrast, the copper pattern lines depicted in FIG. 4 at a magnification 10× greater than that of FIG. 3 show no evidence for corrosion after polishing with the inventive polishing composition.

### EXAMPLE 3

This example shows the effect of concentration of benzotriazole compounds on removal rates for copper and tantalum layers observed with the polishing compositions of the invention.

Nine different polishing compositions were used to separately chemically-mechanically polish similar copper layers and tantalum layers. Each of the compositions comprised 0.5 wt. % of condensation-polymerized silica having a 25 nm primary particle size and 0.2 wt. % (about 9 mM) potassium iodate in water at a pH of 2.2. Composition 3A (control) contained no further ingredients (i.e., no benzotriazole or benzotriazole compound). Composition 3B (comparative) additionally contained benzotriazole at 1 mM concentration. Composition 3C (comparative) additionally contained benzotriazole at 50 mM concentration. Composition 3D (invention) additionally contained 5-methylbenzotriazole at 1 mM concentration. Composition 3E (invention) additionally contained 5-methylbenzotriazole at 50 mM concentration. Composition 3F (invention) additionally contained 1H-benzotriazol-1-ylmethyl isocyamide at 1 mM concentration. Composition 3G (invention) additionally contained 1H-benzotriazol-1-ylmethyl isocyamide at 50 mM concentration. Composition 3H (invention) additionally contained 1H-benzotriazole-1-carboxaldehyde at 1 mM concentration. Composition 3I (invention) additionally contained 1H-benzotriazole-1-carboxaldehyde at 50 mM concentration.

The polishing parameters were as follows: 10 kPa (1.5 psi) downforce pressure of the substrate against the polishing pad, 110 rpm platen speed, 102 rpm carrier speed, 150 mL/min polishing composition flow rate, and use of a Politex CMP pad.

Following use of the polishing compositions, the copper and tantalum removal rates (“Cu RR” and “Ta RR,” respectively) were determined, and the selectivities, defined by the ratio of the copper to tantalum removal rates, were calculated. The results are set forth in Table 1.

TABLE 1
Effect of benzotriazole compounds on
copper and tantalum removal rates

| | | | | | Selec- |
|---|---|---|---|---|---|
| | | | | | tivity |
| Polishing | Benzotriazole | Conc. | Cu RR | Ta RR | (Cu RR/ |
| Composition | Compound | (mM) | (Å/min) | (Å/min) | Ta RR) |
| 3A (control) | None (control) | 0 | 3200 | 600 | 5.33 |
| 3B | benzotriazole | 1 | 3130 | 620 | 5.05 |
| (comparative) | | | | | |
| 3C | benzotriazole | 50 | 990 | 480 | 2.06 |
| (comparative) | | | | | |
| 3D | 5-methylbenzo- | 1 | 3390 | 595 | 5.70 |
| (invention) | triazole | | | | |
| 3E | 5-methylbenzo- | 50 | 15 | 780 | 0.02 |
| (invention) | triazole | | | | |
| 3F | 1-(isocyanomethyl)- | 1 | 3650 | 240 | 15.21 |
| (invention) | 1H-benzotriazole | | | | |
| 3G | 1-(isocyanomethyl)- | 50 | 10 | 90 | 0.11 |
| (invention) | 1H-benzotriazole | | | | |
| 3H | 1H-benzotriazole- | 1 | 3300 | 500 | 6.60 |
| (invention) | 1-carboxaldehyde | | | | |
| 3I | 1H-benzotriazole- | 50 | 5 | 510 | 0.01 |
| (invention) | 1-carboxaldehyde | | | | |

As is apparent from the results set forth in Table 1, all of the inventive polishing compositions containing the benzotriazole compounds at a concentration of 1 mM (i.e., Compositions 3D, 3F, and 3H) exhibited copper removal rates ranging from 1.03 to 1.14 times higher than the copper removal rates exhibited for the control Composition 3A and from 1.05 to 1.17 times higher than observed for comparative Composition 3B, which contained unsubstituted benzotriazole at a concentration of 1 mM. The selectivities exhibited by Compositions 3D, 3F, and 3H, containing 1 mM of benzotriazole compounds, were 1.07 to 2.85 times greater than for the control composition, and were 1.13 to 3.01 times greater than for Composition 3B, containing 1 mM of benzotriazole. Compositions 3E, 3G, and 31 containing 50 mM of benzotriazole compounds exhibited near zero copper removal rates, while comparative Composition 3C, containing 50 mM benzotriazole, exhibited a copper removal rate of 990 A/min. Compositions 3E and 31 further exhibited increased tantalum removal rates, while Composition 3F exhibited a reduced but appreciable tantalum removal rate, as compared to comparative Composition 3C.

### EXAMPLE 4

This example demonstrates removal rates for copper and tantalum exhibited by the inventive polishing composition as compared with a polishing composition containing benzotriazole.

Two different polishing compositions were used to separately chemically-mechanically polish similar copper layers and tantalum layers. Each of the compositions comprised 0.5 wt. % of condensation-polymerized silica having a 25 nm primary particle size and 0.2 wt. % (about 9 mM) potassium iodate in water at a pH of 2.2. Composition 4A (comparative) further contained benzotriazole at a concentration of 10 mM. Composition 4B (invention) further contained 5-methylbenzotriazole at a concentration of 10 mM.

The polishing parameters were as follows: 10 kPa (1.5 psi) downforce pressure of the substrate against the polishing pad, 103 rpm platen speed, 97 rpm carrier speed, 200 mL/min polishing composition flow rate, and use of a Politex CMP pad.

Following use of the polishing compositions, the layers were rinsed with deionized water, and the copper and tantalum removal rates (“Cu RR” and “Ta RR,” respectively) were determined. The results are set forth in Table 2.

TABLE 2
Effect of benzotriazole compounds on
copper and tantalum removal rates

| Polishing Composition | Cu RR (Å/min) | Ta RR (Å/min) |
|---|---|---|
| 4A (comparative) | 3100 | 850 |
| 4B (invention) | 98 | 956 |

As is apparent from the results set forth in Table 2, Composition 4B, containing 5-methylbenzotriazole at a concentration of 10 mM, exhibited a copper removal rate that was about 0.032 times the copper removal rate observed with Composition 4A, which contained benzotriazole at a concentration of 10 mM. Further, the tantalum removal rate exhibited by Composition 4B was about 1.12 times greater than that observed with comparative Composition 4A.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) an abrasive,
(b) about 0.5 mM to about 100 mM of a benzotriazole compound having the general structure 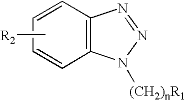
wherein R₁ is selected from the group consisting of H, —OH, —CHO, —CN, and —NC, n is an integer of 0 to about 6, and R₂ is selected from the group consisting of H, C₁-C₆ alkyl, F, Cl, and Br, with the proviso that when R₁ is H and n=0, then R₂ cannot be H,
(c) an oxidizing agent selected from the group consisting of iodate compounds, organic oxidizing agents, and mixtures thereof, and
(d) water,
wherein the polishing composition comprises substantially no organic carboxylic acid having a molecular weight of less than about 500 Daltons, and wherein the polishing composition comprises no alkyl sulfate having a molecular weight of less than about 500 Daltons.

2. The polishing composition of claim 1, wherein the abrasive is condensation-polymerized silica.

3. The polishing composition of claim 2, wherein the condensation-polymerized silica is present in an amount of about 0.1 wt. % to about 10 wt. %.

4. The polishing composition of claim 1, wherein the benzotriazole compound is selected from the group consisting of 4-methylbenzotriazole, 5-methylbenzotriazole, 1H-benzotriazole-1-carboxaldehyde, 1-(isocyanomethyl)-1H-benzotriazole, 1H-benzotriazole-1-acetonitrile, 1H-benzotriazole-1-methanol, and combinations thereof.

5. The polishing composition of claim 1, wherein the oxidizing agent is an iodate compound.

6. The polishing composition of claim 5, wherein the iodate compound is present at a concentration of about 0.1 mM to about 1 M.

7. The polishing composition of claim 1, wherein the oxidizing agent is an organic oxidizing agent.

8. The polishing composition of claim 7, wherein the organic oxidizing agent is selected from the group consisting of anthraquinones, indigos, and combinations thereof.

9. The polishing composition of claim 8, wherein the organic oxidizing agent is selected from the group consisting of anthraquinone-2,6-disulfonic acid, anthraquinone-2-sulfonic acid, anthraquinone-1,8-disulfonic acid, anthraquinone-1,5-disulfonic acid, acid blue 45, salts thereof, and combinations thereof.

10. The polishing composition of claim 7, wherein the organic oxidizing agent is present at a concentration of about 0.1 mM to about 10 mM.

11. A method of chemically-mechanically polishing a substrate, which method comprises:
(i) providing a substrate,
(ii) contacting the substrate with a polishing pad and a chemical-mechanical polishing composition comprising:
(a) an abrasive,
(b) about 0.5 mM to about 100 mM of a benzotriazole compound having the general structure 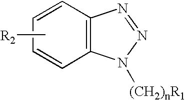
wherein R₁ is selected from the group consisting of H, —OH, —CHO, —CN, and —NC, n is an integer of 0 to about 6, and R₂ is selected from the group consisting of H, C₁-C₆ alkyl, F, Cl, and Br, with the proviso that when R₁ is H and n=0, then R₂ cannot be H,
(c) an oxidizing agent selected from the group consisting of iodate compounds, organic oxidizing agents, and mixtures thereof, and
(d) water,
wherein the polishing composition comprises substantially no organic carboxylic acid having a molecular weight of less than about 500 Daltons, and wherein the polishing composition comprises no alkyl sulfate having a molecular weight of less than about 500 Daltons,
(ii) moving the polishing pad relative to the substrate with the chemical-mechanical polishing composition therebetween, and
(iii) abrading at least a portion of the substrate to polish the substrate.

12. The method of claim 11, wherein the abrasive is condensation-polymerized silica.

13. The method of claim 12, wherein the condensation-polymerized silica is present in an amount of about 0.1 wt. % to about 10 wt. %.

14. The method of claim 11, wherein the benzotriazole compound is selected from the group consisting of 4-methylbenzotriazole, 5-methylbenzotriazole, 1H-benzotriazole-1-carboxaldehyde, 1-(isocyanomethyl)-1H-benzotriazole, 1H-benzotriazole-1-acetonitrile, 1H-benzotriazole-1-methanol, and combinations thereof.

15. The method of claim 11, wherein the oxidizing agent is an iodate compound.

16. The method of claim 15, wherein the iodate compound is present at a concentration of about 0.1 mM to about 1 M.

17. The method of claim 11, wherein the oxidizing agent is an organic oxidizing agent.

18. The method of claim 17, wherein the organic oxidizing agent is selected from the group consisting of anthraquinones, indigos, and combinations thereof.

19. The method of claim 18, wherein the organic oxidizing agent is selected from the group consisting of anthraquinone-2,6-disulfonic acid, anthraquinone-2-sulfonic acid, anthraquinone-1,8-disulfonic acid, anthraquinone-1,5-disulfonic acid, acid blue 45, salts thereof, and combinations thereof.

20. The method of claim 17, wherein the organic oxidizing agent is present at a concentration of about 0.1 mM to about 10 mM.

21. The method of claim 11, wherein the substrate comprises copper.

22. The method of claim 21, wherein the substrate further comprises a barrier layer comprising tantalum.

23. The method of claim 22, wherein the substrate further comprises a dielectric layer.

24. The method of claim 23, wherein the dielectric layer is selected from the group consisting of silicon dioxide, carbon-doped silicon dioxide, and organically modified silicon glass.
